(19) United States
(12) Patent Application Publication
(10) Pub. No.: US 2020/0194058 A1
(43) Pub. Date: Jun. 18, 2020

(54) LAYOUT PATTERN FOR SRAM AND MANUFACTURING METHODS THEREOF

(71) Applicant: UNITED MICROELECTRONICS CORP., Hsin-Chu City (TW)

(72) Inventors: Te-Chang Hsu, Tainan City (TW); Cheng-Pu Chiu, New Taipei City (TW); Chun-Jen Huang, Tainan City (TW); Cheng-Yeh Huang, Tainan City (TW); Che-Hsien Lin, Taoyuan City (TW); Yao-Jhan Wang, Tainan City (TW)

(21) Appl. No.: 16/218,372

(22) Filed: Dec. 12, 2018

(51) Int. Cl. G11C 11/412; H01L 27/11; H01L 23/528

(52) U.S. Cl. CPC G11C 11/412; H01L 27/0203; H01L 23/528; H01L 27/1104

(57) ABSTRACT

The present invention provides a static random access memory (SRAM), the SRAM includes a substrate, a SRAM pattern disposed on the substrate, wherein the SRAM pattern at least includes a first gate structure, a second gate structure and a third gate structure, arranged along a first direction, wherein the second gate structure and the third gate structure are parallel to the first gate structure, and a gap is disposed between the second gate structure and the third gate structure, and wherein the first gate structure is composed of a first elongated structure, a second elongated structure and a curved structure disposed between the first elongated structure and the second elongated structure, and wherein the curved structure is aligned with the gap along a second direction, and an interconnection contact structure disposed between the first gate structure and the second gate structure, and arranged along the first direction.

### BACKGROUND OF THE INVENTION

### 1. Field of the Invention

The invention relates to a static random access memory (SRAM), and more particularly, to a SRAM having a curved gate structure.

### 2. Description of the Prior Art

An embedded static random access memory (SRAM) comprises a logic circuit and a static random access memory connected to the logic circuit. SRAM is a kind of volatile memory cell, which means it preserves data only while power is continuously applied. SRAM is built of cross-coupled inverters that store data during the time that power remains applied, unlike dynamic random access memory (DRAM) that needs to be periodically refreshed. Because of its high access speed, SRAM is also used in computer systems as a cache memory.

However, as gap of the exposure process decreases, it has been difficult for the current SRAM architecture to produce desirable patterns. Hence, how to enhance the current SRAM architecture for improving exposure quality has become an important task in this field.

### SUMMARY OF THE INVENTION

The present invention provides a static random access memory (SRAM), the SRAM includes a substrate, a SRAM pattern disposed on the substrate, wherein the SRAM pattern at least includes a first gate structure, a second gate structure and a third gate structure, arranged along a first direction, wherein the second gate structure and the third gate structure are parallel to the first gate structure, and a gap is disposed between the second gate structure and the third gate structure, and wherein the first gate structure is composed of a first elongated structure, a second elongated structure and a curved structure disposed between the first elongated structure and the second elongated structure, and wherein the curved structure is aligned with the gap along a second direction, and an interconnection contact structure disposed between the first gate structure and the second gate structure, and arranged along the first direction.

The present invention further provides a method for forming a static random access memory (SRAM). First, a substrate is provided, and a SRAM pattern is formed on the substrate, the SRAM pattern at least includes a first gate structure, a second gate structure and a third gate structure, arranged along a first direction, wherein the second gate structure and the third gate structure are parallel to the first gate structure, and a gap is disposed between the second gate structure and the third gate structure, and wherein the first gate structure is composed of a first elongated structure, a second elongated structure and a curved structure disposed between the first elongated structure and the second elongated structure, and wherein the curved structure is aligned with the gap along a second direction, and an interconnection contact structure disposed between the first gate structure and the second gate structure, and arranged along the first direction.

The present embodiment is characterized in that, from the top view, some of the gate structure includes one curved structure disposed between two elongated structures, and the curved structure is aligned with the gap along the second direction.

The purpose of forming this structure is that the applicant has found that as the size of the SRAM is gradually reduced, it is easier for the components to contact each other during the manufacturing process to cause a short circuit. In the process of fabricating the SRAM, since the gate structure is divided by a slot cut manner, especially in the region that the local interconnection aligned with the gap of two adjacent gate structures is easily contacted with the surrounding gate structure, causing the short circuit phenomenon. Therefore, the present invention adjusts the shape of the gate structure of the region where the short circuit phenomenon is likely to occur by the OPC (optical proximity correction) process, to avoid the above short circuit problem.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a circuit diagram of an eight-transistor SRAM (8T-SRAM) cell according to a first preferred embodiment of the present invention.

FIG. 2 illustrates a layout diagram of a SRAM according to the first preferred embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

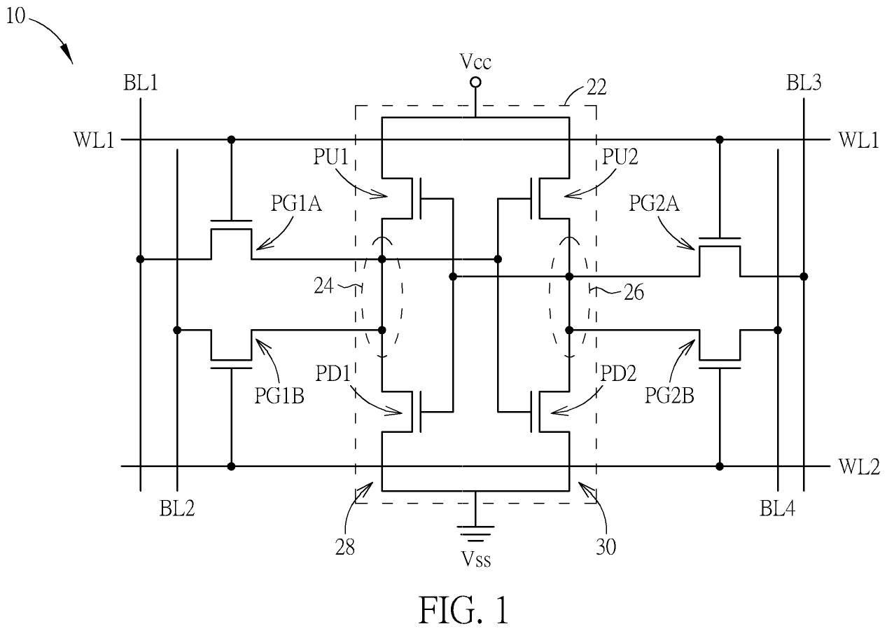

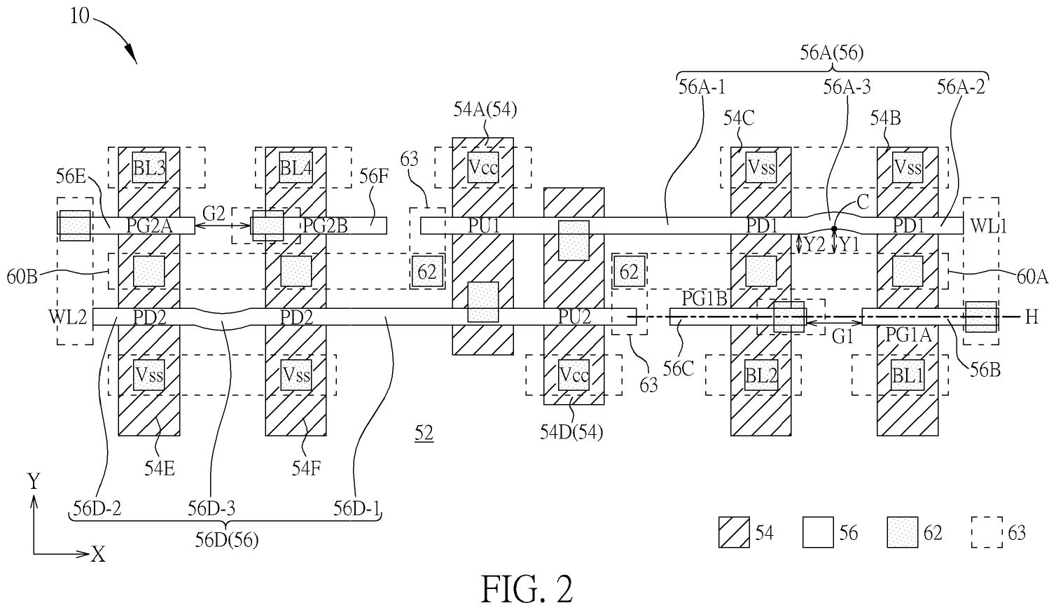

Referring to FIGS. 1-2, FIG. 1 illustrates a circuit diagram of an eight-transistor SRAM (8T-SRAM) cell according to a first preferred embodiment of the present invention, and FIG. 2 illustrates a layout diagram of an 8T-SRAM according to the first preferred embodiment of the present invention.

As shown in FIGS. 1-2, the SRAM device of the present invention preferably includes at least one SRAM cell, each SRAM cell including an eight-transistor SRAM (8T-SRAM) cell 10.

In this embodiment, at least one 8T-SRAM cell 10 is formed on a substrate 52, each 8T-SRAM cell 10 is composed of a first pull-up transistor PU1, a second pull -up transistor PU2, and a first pull-down transistor PD1, a second pull-down transistor PD2, a first pass gate transistor PG1A, a second pass gate transistor PG1B, a third pass gate transistor PG2A and a fourth pass gate transistor PG2B. These eight transistors constitute a set of flip-flops. The first and the second pull-up transistors PU1 and PU2, and the first and the second pull-down transistors PD1 and PD2 constitute a latch circuit 22 that stores data in the storage nodes 24 and 26. Since the first and the second pull-up transistors PU1 and PU2 act as power load devices, they can be replaced by resistors. Under this circumstance, the static random access memory becomes a four-transistor SRAM (4T-SRAM). In this embodiment, the first and the second pull-up transistors PU1 and PU2 preferably share a source/drain region and electrically connect to a voltage source (voltage node) Vcc, and the first and the second pull-down transistors PD1 and PD2 share a source/drain region and electrically connect to a voltage source (voltage node) Vss.

Preferably, the first and the second pull-up transistors PU1 and PU2 of the 8T-SRAM cell 10 are composed of p-type metal oxide semiconductor (PMOS) transistors; the first and the second pull-down transistors PD1 and PD2, the first pass gate transistors PG1A, the second pass gate transistors PG1B, the third pass gate transistors PG2A and the fourth pass gate transistors PG2B composed of n-type metal oxide semiconductor (NMOS) transistors, but not limited thereto. The first pull-up transistor PU1 and the first pull-down transistor PD1 constitute an inverter, which further form a series circuit 28. One end of the series circuit 28 is connected to a voltage source Vcc and the other end of the series circuit 28 is connected to a voltage source Vss. Similarly, the second pull-up transistor PU2 and the second pull-down transistor PD2 constitute another inverter and a series circuit 30. One end of the series circuit 30 is connected to the voltage source Vcc and the other end of the series circuit 30 is connected to the voltage source Vss. Each pass gate transistors (including the first pass gate transistor PG1A, the second pass gate transistor PG1B, the third pass gate transistor PG2A and the fourth pass gate transistor PG2B) configured with the two cross-coupled inverters respectively, wherein each of the at least one pull-up transistor (PUs), the at least one pull-down transistors (PDs), and the at least two pass gate transistor (PGs) includes a planar transistor crossing the diffusion region.

The storage node 24 is connected to the respective gates of the second pull-down transistor PD2 and the second pull-up transistor PU2. The storage node 24 is also connected to the drain of the first pull-down transistor PD1, the drain of the first pull-up transistor PU1, the drain of the first pass gate transistor PG1A and the drain of the second pass gate transistor PG1B. Similarly, the storage node 26 is connected to the respective gates of the first pull-down transistor PD1 and first the pull-up transistor PU1. The storage node 26 is also connected to the drain of the second pull-down transistor PD2, the drain of the second pull-up transistor PU2, the drain of the third pass gate transistor PG2A and the drain of the fourth pass gate transistor PG2B. The gates of the first pass gate transistor PG1A and the third pass gate transistor PG1B are respectively coupled to a first word line (WL1); the gates of the second pass gate transistor PG1B and the fourth pass gate transistor PG2B are respectively coupled to a second word line (WL2); the source of the first pass gate transistor PG1A is coupled to a first bit line (BL1); the source of the second pass gate transistor PG1B is coupled to a second bit line (BL2); the source of the third pass gate transistor PG2A is coupled to a third bit line (BL3); and the source of the fourth pass gate transistor PG2B is coupled to a fourth bit line (BL4).

Please refer to FIG.2, in this embodiment, an 8T-SRAM cell 10 is disposed on the substrate 52, such as a silicon substrate or silicon-on-insulator (SOI) substrate. A plurality of diffusion regions 54 may be formed in the substrate 52. The diffusion regions 54 are arranged parallel with each other. In addition, a shallow trench isolation (STI, not shown) is disposed between each diffusion region 54.

In addition, a plurality of gate structures 56 are formed on the substrate 52. Each transistor (including the first pull-up transistor PU1, the first pull -down transistor PD1, the second pull-up transistor PU2, the second pull-down transistor PD2, the first pass gate transistor PG1A, the second pass gate transistor PG1B, the third pass gate transistor PG2A, and the fourth pass gate transistor PG2B mentioned above) comprises a gate structure 56 crossing over at least one diffusion region 54, to form the transistors.

In the present invention, the same gate structure simultaneously crosses a plurality of different diffusion regions 54, which helps to increase the gate width of the transistor. In other words, on the equivalent circuit, a plurality of transistors are connected in parallel with each other. Therefore, within a limited area, the read current (Iread) of the transistor is increased, and the operation speed of the overall SRAM can be accelerated.

As shown in FIG. 2, in order to clearly define the positions of the diffusion regions 54 and the gate structures 56, the diffusion regions 54 and the gate structures 56 are labeled indifferent symbols. More precisely, the diffusion regions 54 include a first diffusion region 54A, a second diffusion region 54B, a third diffusion region 54C, and a fourth diffusion region. 54D, a fifth diffusion region 54E, and a sixth diffusion region 54F. The first diffusion region 54A, the second diffusion region 54B and the third diffusion region 54C belong to the same inverter (please also refer to FIG. 1), the fourth diffusion region 54D, the fifth diffusion region 54E and the sixth diffusion region 54F belongs to another inverter. In addition, the gate structure 56 include a first gate structure 56A, a second gate structure 56B, a third gate structure 56C, a fourth gate structure 56D, a fifth gate structure 56E, and a sixth gate structure 56F. It can be understood that all of the first diffusion region 54A to the sixth diffusion region 54F belong to the diffusion region 54. All of the first gate structure 56A to the sixth gate structure 56F belong to the gate structure 56.

Besides, in the process for forming the gate structures mentioned above, one gate structure may be divided into two gate structures by a slot cut process. For example, by a slot cut process, one gate structure may be divided into the second gate structure 56B and the third gate structure 56C, therefore, the second gate structure 56B and the third gate structure 56C have a same symmetry axis (such as the horizontal line H shown in FIG.2). On the other hand, since the first gate structure 56A and the second gate structure 56B are parallel to each other, the first gate structure 56A and the second gate structure 56B contain different symmetry axes.

In this embodiment, the second gate structure 56B, the third gate structure 56C, the fifth gate structure 56E, the sixth gate structure 56F, the first part 56A-1, the second part 56A-2 of the first gate structure 56A, and the first part 56D-1, the second part 56D-2 of the fourth gate structure 56D are all arranged along a first direction (such as the X-axis), and each of the diffusion regions 54 is arranged along a second direction (such as the Y-axis). Preferably, the first direction and the second direction are perpendicular to each other.

It should be noted that the first gate structure 56A in this embodiment comprises two elongated structures and one curved structure disposed between the two elongated structures. Similarly, the fourth gate structure 56D in this embodiment comprises two elongated structures and one curved structure disposed between the two elongated structures. More precisely, the first gate structure 56A include a first part 56A-1, a second part 56A-2 and a third part 56A-3. The first part 56A-1 and the second part 56A-2 are two elongated structures, and the third part 56A-3 is a curved structure disposed between the disposed the first part 56A-1 and the second part 56A-2. On the other hand, the fourth gate structure 56D include a first part 56D-1, a second part 56D-2 and a third part 56D-3. The first part 56D-1 and the second part 56D-2 are two elongated structures, and the third part 56D-3 is a curved structure disposed between the disposed the first part 56D-1 and the second part 56D-2. Preferably, both the first gate structure 56A and the fourth gate structure 56D are integrally formed structures (one-piece structures, or monolithically formed structures). Taking the first gate structure 56A as an example, the first part 56A-1, the second portion 56A-2 and the third part 56A-3 of the first gate structure 56A are directly contacting with each other, made of the same material and are simultaneously formed on the same plane (such as the XY plane).

In this embodiment, a first gap G1 is defined between the second gate structure 56B and the third gate structure 56C, and a second gap G2 is defined between the fifth gate structure 56E and the sixth gate structure 56F. In the present invention, the third part 56A-3 of the first gate structure 56A is aligned with the first gap G1 along the second direction (such as the Y-axis), and the third part 56D-3 of the fourth gate structure 56D is aligned with the second gap G2 along the second direction (such as the Y-axis).

In this embodiment, the first part 56A-1 of the first gate structure 56A crosses the first diffusion region 54A to form a first pull-up transistor PU1, the first part 56A-1 and the second part 56A-2 of the first gate structure 56A crosses the second diffusion region 54B and the third diffusion region 54C to form a first pull-down transistor PD1; the second gate structure 56B crosses the second diffusion region 54B to form a first access transistor PG1A; the third gate structure 56C crosses the third diffusion region 54C to form a second access transistor PG1B; the first part 56D-1 of the fourth gate structure 56D crosses the fourth diffusion region 54D to form a second pull-up transistor PU2, the first part 56D-1 and the second part 56D-2 of the fourth gate structure 56D crosses the fifth diffusion region 54E and the sixth diffusion region 54F to form a second pull-down transistor PD2; the fifth gate structure 56E crosses the fifth diffusion region 54E to form a third access transistor PG2A; and the sixth gate structure 56F crosses the sixth diffusion region 54F to form a fourth access transistor PG2B.

It should be noted that, taking the first gate structure 56A in FIG. 2 as an example, the first part 56A-1 and the second part 56A-2 of the first gate structure 56A respectively crosses two different diffusion regions to form two pull-down transistors, but in equivalent circuit, the two pull-down transistors are connected in parallel with each other, so the read current of the first pull-down transistor PD1 is equivalent to the sum of the read currents of the two different pull-down transistors, so that the read current of the first pull-down transistor is greatly increased, and the overall SRAM performance is increased too. Similarly, the fourth gate structure 56D crosses different diffusion regions, and the read current of the second pull-down transistor PD2 can also be increased.

It should be note that the first gate structure 56A in this embodiment comprises two elongated structures and one curved structure disposed between the two elongated structures. On the other hand, the fourth gate structure 56D in this embodiment comprises two elongated structures and one curved structure disposed between the two elongated structures. Therefore, the third part 56A-3 (curved structure) of the first gate structure 56A is disposed between the gates of two parallel transistors (i.e., two parallel transistors PD1), and the third part 56D-3 (curved structure) of the fourth gate structure 56D is disposed between the gates of two parallel transistors (i.e., two parallel transistors PD2).

In addition, a plurality of contact plugs 62 and a plurality of contact layers 63 are formed on the substrate 52, the contact plugs 62 and the contact layers 63 are used to connect different transistors (e.g., a gate of the second pull-up transistor PU2 and drain of the first pull-up transistor PU1 are connected to each other through the contact plug 62 and the contact layer 63), or used to connect the transistors to other elements (e.g., a source of the first pull-up transistor PU1 is connected to the voltage source Vcc). In FIG.2, the elements that connected to each contact plug or each contact layer (for example, the voltage source Vcc, the voltage source Vss, the first word line WL1, the second word line WL2, the first bit line BL1, the second bit line BL2, the third bit line BL3, and the fourth bit line BL4) are labeled on each contact plug 62 or each contact layer 63 directly, to clearly represent the corresponding elements of the contact plugs 62 and the contact layers 63.

The present invention further includes a first local interconnection layer 60A and a second local interconnection layer 60B arranged along the first direction. In addition, the first local interconnection layer 60A crosses the second diffusion region 54B and the third diffusion region 54C, and the gate of the second pull-up transistor PU2, the drain of the first pull-down transistor PD1, the drain of the first access transistor PG1A and the drain of the second access transistor PG1B are connected together (it corresponding to the storage node 24 in FIG. 1). Further, it is to be noted that the first local interconnection layer 60A and the fourth diffusion region 54D do not overlapped with each other. Besides, the second local interconnection layer 60B crosses the fifth diffusion region 54E and the sixth diffusion region 54F, and the gate of the first pull-up transistor PU1, the drain of the second pull-down transistor PD2, the drain of the third access transistor PG2A and the drain of the fourth access transistor PG2B are connected together (it corresponding to the storage node 26 in FIG. 1). Furthermore, it is to be noted that the second local interconnection layer 60B does not overlap the first diffusion region 54A.

It is worth noting that in FIG.2, elements having the same properties contain the same mesh pattern. For example, all gate structures are depicted in the same mesh pattern, and all contact plugs are also depicted in the same mesh pattern. The remaining elements depicted in the present invention are also following this rule. Besides, the first local interconnection layer 60A or the second local interconnection layer 60B have the same properties as the contact layer 63, and they are represented by the same mesh pattern.

In the subsequent steps, other dielectric layers, contact structures, metal layers, and the like are formed to be stacked over the above elements. Since the present invention does not limit the shape, the number, and the like of the subsequent contact structure and the metal layer, it will not be described herein.

The present embodiment is characterized in that, from the top view, some of the gate structure (for example, the first gate structure 56A or the fourth gate structure 56D) includes one curved structure disposed between two elongated structures, and the curved structure is aligned with the gap (G1 or G2) along the second direction (such as Y-axis). In the present invention, the third part 56A-3 of the first gate structure 56A is an “upward curved structure”. On the other hand, the third part 56D-3 of the fourth gate structure 56D is an “downward curved structure”. More precisely, taking the first gate structure 56A, the second gate structure 56B and the third gate structure 56C as an example, the third part 56A-3 of the first gate structure 56A has a central point C, and the vertical distance between the central point C and the first local interconnection layer 60A (labeled as Y1 in FIG.2) is larger than the vertical distance between the first part 56A-1 of the first gate structure 56A and the first local interconnection layer 60A (labeled as Y2 in FIG.2).

The purpose of forming this structure is that the applicant has found that as the size of the SRAM is gradually reduced, it is easier for the components to contact each other during the manufacturing process to cause a short circuit. In the process of fabricating the SRAM, since the gate structure is divided by a slot cut process, especially in the region that the local interconnection near the gap of two adjacent gate structures is easily contacted with the surrounding gate structure, causing the short circuit phenomenon. Therefore, the present invention adjusts the shape of the gate structure of the region where the short circuit phenomenon is likely to occur by the OPC (optical proximity correction) process. The third part 56A-3 of the first gate structure 56A is a curved structure, and since the third part 56A-3 of the first gate structure 56A is far from the local interconnection 60A, it is less likely to make a short circuit in contact with the local interconnection 60A.

Besides, each of the above-described transistors is exemplified by a planar transistor, that is, a gate structure crosses over the diffusion region. However, in the present invention, a plurality of fin structures may be formed on the substrate, and the original planar transistor may be replaced by a fin-FET, and this structure is also within the scope of the present invention. In addition, although the 8T-SRAM is taken as an example in the above embodiment, the present invention is not limited thereto. The present invention is also applicable to other components such as 6T-SRAM, 10T-SRAM or other suitable SRAM.

Those skilled in the art will readily observe that numerous modifications and alterations of the device and method may be made while retaining the teachings of the invention. Accordingly, the above disclosure should be construed as limited only by the metes and bounds of the appended claims.

1. A static random access memory (SRAM), comprising:
a substrate, a SRAM pattern disposed on the substrate, wherein the SRAM pattern at least comprising:
a first gate structure, a second gate structure and a third gate structure, arranged along a first direction, wherein the second gate structure and the third gate structure are parallel to the first gate structure, and a gap is disposed between the second gate structure and the third gate structure, and wherein the first gate structure is composed of a first elongated structure, a second elongated structure and a curved structure disposed between the first elongated structure and the second elongated structure, wherein the curved structure is aligned with the gap along a second direction; and
an interconnection contact structure disposed between the first gate structure and the second gate structure, and arranged along the first direction.

2. The SRAM of claim 1, wherein the first direction and the second direction are perpendicular to each other.

3. The SRAM of claim 2, wherein the first direction and the second direction form a plane, and the SRAM is located on the plane.

4. The SRAM of claim 1, wherein the second gate structure and the third gate structure comprise a same symmetry axis.

5. The SRAM of claim 1, wherein the second gate structure and the first gate structure comprise different symmetry axes.

6. The SRAM of claim 1, wherein the SRAM pattern further comprising:
a first inverter and a second inverter constituting a latch circuit, wherein the first inverter includes a first pull-up transistor (PU1) and a first pull-down transistor (PD1), and the second inverter includes a second pull-up transistor (PU2) and a second pull-down transistor (PD2), a first pass gate transistor (PG1A), a second pass gate transistor (PG1B), a third pass gate transistor (PG2A) and a fourth pass gate transistor (PG2B).

7. The SRAM of claim 6, wherein parts of the first elongated structure is a gate of the PU1, partsated structure is a gate of the PD1, and the second elongated structure is a gate of the PD1.

8. The SRAM of claim 6, wherein the second gate structure is a gate of the PG1A.

9. The SRAM of claim 1, wherein the curved structure of the first gate structure comprises a central point, and the distance between the central point and the interconnection contact structure along the second direction is larger than the distance between the first elongated structure and the interconnection contact structure along the second direction.

10. The SRAM of claim 1, further comprising performing an optical proximity correction (OPC) process to make curved structure of the first gate structure.

11. (canceled)

12. A method for forming a static random access memory (SRAM), comprising:
providing a substrate, a SRAM pattern is formed on the substrate, wherein the SRAM pattern at least comprising:
a first gate structure, a second gate structure and a third gate structure, arranged along a first direction, wherein the second gate structure and the third gate structure are parallel to the first gate structure, and a gap is disposed between the second gate structure and the third gate structure, and wherein the first gate structure is composed of a first elongated structure, a second elongated structure and a curved structure disposed between the first elongated structure and the second elongated structure, wherein the curved structure is aligned with the gap along a second direction; and
a local interconnection layer disposed between the first gate structure and the second gate structure, and arranged along the first direction.

13. The method of claim 12, wherein the first direction and the second direction are perpendicular to each other.

14. The method of claim 13, wherein the first direction and the second direction form a plane, and the SRAM is located on the plane.

15. The method of claim 12, wherein the second gate structure and the third gate structure comprise a same symmetry axis.

16. The method of claim 12, wherein the second gate structure and the first gate structure comprise different symmetry axes.

17. The method of claim 12, wherein the SRAM pattern further comprising:
a first inverter and a second inverter constituting a latch circuit, wherein the first inverter includes a first pull-up transistor (PU1) and a first pull-down transistor (PD1), and the second inverter includes a second pull-up transistor (PU2) and a second pull-down transistor (PD2), a first pass gate transistor (PG1A), a second pass gate transistor (PG1B), a third pass gate transistor (PG2A) and a fourth pass gate transistor (PG2B).

18. The method of claim 17, wherein parts of the first elongated structure is a gate of the PU1, parts of the first elongated structure is a gate of the PD1, and the second elongated structure is a gate of the PD1.

19. The method of claim 17, wherein the second gate structure is a gate of the PG1A.

20. (canceled)
